(19) United States
(12) Patent Application Publication
(10) Pub. No.: US 2026/0025922 A1
(43) Pub. Date: Jan. 22, 2026

(54) DUAL DIFFERENTIAL VIA DESIGN ON A PRINTED CIRCUIT BOARD

(71) Applicant: DELL PRODUCTS L.P., Round Rock, TX (US)

(72) Inventors: Sandor Farkas, Round Rock, TX (US); Chang-Kai Chu, Zhongli District (TW); Bhyrav Mutnury, Round Rock, TX (US)

(21) Appl. No.: 18/774,633

(22) Filed: Jul. 16, 2024

(51) Int. Cl. H05K 1/11; H05K 1/02; H05K 3/00; H05K 3/42

(52) U.S. Cl. CPC H05K 1/115; H05K 1/0222; H05K 3/0047; H05K 3/429; H05K 2201/09227; H05K 2201/093

(57) ABSTRACT

An information handling system includes a printed circuit board having first and second vias fabricated through the printed circuit board. The first via includes first, second, third, and fourth via portions. The first via portion is connected to a first trace of a first differential pair. The second via portion is connected to a second trace of the first differential pair of the printed circuit board. The third and fourth via portions are connected to a ground plane layer of the printed circuit board. The second via includes fifth, sixth, seventh, and eighth via portions. The fifth via portion is connected to a first trace of a second differential pair. The sixth via portion is connected to a second trace of the second differential pair of the printed circuit board. The seventh and eighth via portions are connected to the ground plane layer of the printed circuit board.

### FIELD OF THE DISCLOSURE

The present disclosure generally relates to information handling systems, and more particularly relates to a dual differential via design on a printed circuit board.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system includes a printed circuit board having first and second vias fabricated through the printed circuit board. The first via includes a first conductive metal plating, and first, second, third, and fourth via portions formed in the first conductive metal plating. The first via portion may be connected to a first trace of a first differential pair of the printed circuit board. The second via portion may be connected to a second trace of the first differential pair of the printed circuit board. The third and fourth via portions may be connected to a ground plane layer of the printed circuit board. The second via includes a second conductive metal plating, and fifth, sixth, seventh, and eighth via portions are formed in the second conductive metal plating. The fifth via portion may be connected to a first trace of a second differential pair of the printed circuit board. The sixth via portion may be connected to a second trace of the second differential pair of the printed circuit board. The seventh and eighth via portions may be connected to the ground plane layer of the printed circuit board.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a portion of a printed circuit board with signal vias connected to pads of a differential pair according to prior art;

FIG. 2 is a diagram of a portion of a printed circuit board with differential signal via connected to pads of a differential pair according to prior art;

FIG. 3 is a diagram of a portion of a printed circuit board with differential signal vias connected to pads of two differential pairs according to at least one embodiment of the present disclosure;

FIG. 4 is a diagram of a portion of a printed circuit board with differential signal vias connected to pads of two differential pairs according to at least one embodiment of the present disclosure;

FIG. 5a is a diagram of a portion of a printed circuit board with differential signal vias connected to pads of two differential pairs according to at least one embodiment of the present disclosure;

FIG. 5b is a diagram of a portion of a printed circuit board with differential signal vias connected to pads of two differential pairs according to at least one embodiment of the present disclosure;

FIG. 6 is a flow diagram of a method for creating two different signal vias and connecting the differential signal vias to pads of two differential pairs according to at least one embodiment of the present disclosure; and

FIG. 7 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

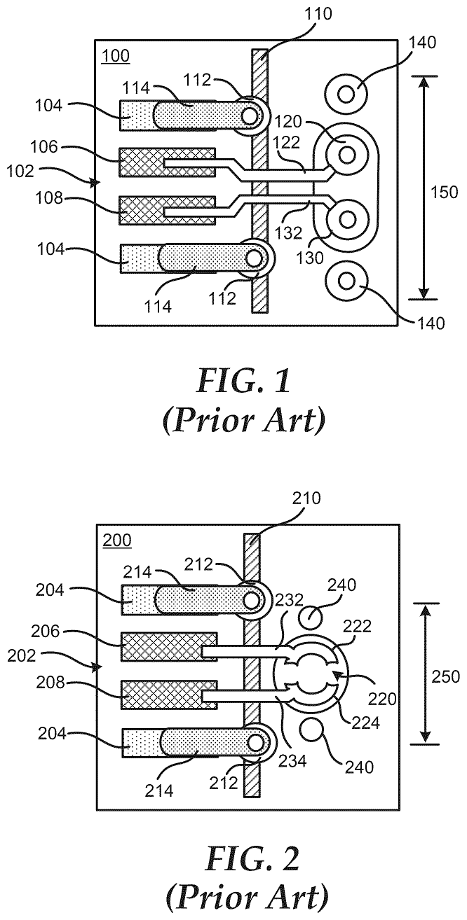

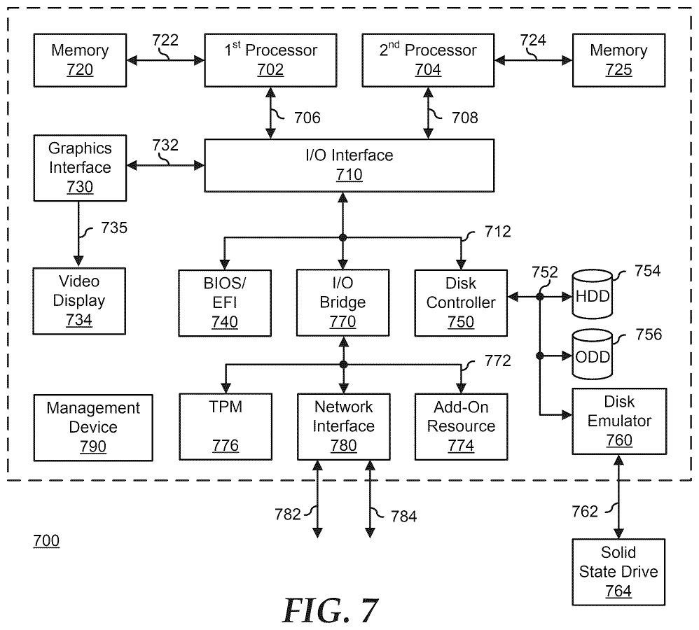

FIG. 1 illustrates a printed circuit board (PCB) 100 of an information handling system, such as information handling system 700 of FIG. 7, according to prior art in the field. For purpose of this disclosure information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system can be a personal computer, a laptop computer, a smart phone, a tablet device or other consumer electronic device, a network server, a network storage device, a switch, a router, or another network communication device, or any other suitable device and may vary in size, shape, performance, functionality, and price.

PCB 100 includes a differential pair 102 and ground pads 104. Differential pair 102 includes pads 106 and 108. Each ground pad 104 may be physically and electrically coupled to a ground layer 110 of PCB 100 by a respective ground via 112 and ground trace 114. PCB 100 also includes signal vias 120 and 130. Signal via 120 is electrically and physically connected to pad 106 of differential pair 102 by a signal trace 122. Similarly, signal via 130 is electrically and physically connected to pad 108 of differential pair 102 by a signal trace 132. PCB 100 further includes ground vias 140 associated with signal vias 120 and 130. Ground vias 140, signal via 120, and signal via 130 may cover a particular length 150 on PCB 100.

In an example, a combination of ground pad 104, ground plane layer 110, ground via 112, and ground trace 114 may reduce crosstalk between differential pair 102 and an adjacent differential pair. The details of PCB manufacture, and particularly the forming of vias and traces on a PCB are known in the art and will not be further described herein, except as needed to illustrate the current embodiments.

PCB 100 may be utilized for transmission of high speed signals. In this situation, routing for the high speed signal on PCB 100 may need a lot of differential vias for signals. Additionally, PCB 100 may include a lot of ground vias to control a target impedance of a differential pair and to reduce crosstalk between adjacent differential pairs. The via design of PCB 100 may utilize via to via spacing to control the impedance of the differential pair, and may add one or more grounds vias to reduce crosstalk. This via design in PCB 100 may utilize a lot of routing space available in the PCB. In some cases, traditional differential via designs may exceed an available real estate for routing on PCB 100 when there is high density PCB routing.

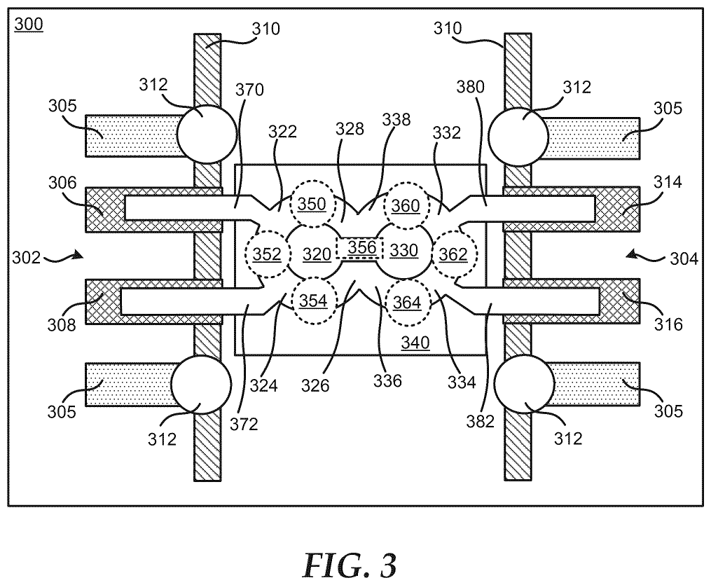

FIG. 2 illustrates a portion of a PCB 200 of an information handling system, such as information handling system 700 of FIG. 7, according to prior art in the field. PCB 200 includes a differential pair 202 and ground pads 204. Differential pair 202 includes pads 206 and 208. Each ground pad 204 may be physically and electrically coupled to a ground layer 210 of PCB 200 by a respective ground via 212 and ground trace 214. PCB 200 also includes signal via 220, which in turn is divided into separate via portions 222 and 224. Signal via portion 222 is electrically and physically connected to pad 206 of differential pair 202 by a signal trace 232. Similarly, signal via portion 224 is electrically and physically connected to pad 208 of differential pair 202 by a signal trace 234. PCB 200 further includes ground vias 240 associated with signal via portions 222 and 224 of via 220. Ground vias 240, signal via 220 may cover a particular length 250 on PCB 200.

Signal via 220 (portions 222 and 224) and ground vias 212 and 240 are utilized to interconnect two or more different metal layers within PCB 200. Additionally, signal via 220 and ground vias 212 and 240 may be utilized to connect the two or more different metal layers within PCB 200 with metal traces and/or metal pads on a surface of the PCB, such as pads 204, 206, and 208. While portions 222 and 224 of signal via 220 are illustrated and described as connecting metal layers within PCB 200 to respective pads 206 and 208 via respective traces 232 and 234 on the surface of the PCB, traces 232 and 234 may be located within any layer within the PCB and portions 222 and 224 of signal via 220 may perform substantially similar functions.

In an example, signal via 220 with via portions 222 and 224 may create a smaller structure as compared to signal vias 120 and 130 of PCB 100 in FIG. 1. For example, length 150 consumed by ground vias 140 and signal vias 120 and 130 on PCB 100 of FIG. 1 is greater than length 250 consumed by ground vias 240 and signal via portions 222 and 224 of signal via 220 on PCB 200. Thus, the layout space of signal via 220 and ground vias 240 on PCB 200 is less than the layout space of signal vias 120 and 130 and ground vias 140 on PCB 100 of FIG. 1. In this example, the structure of signal via 220 with via portions 222 and 224 may enable a greater density of vias and signal traces on PCB 200 as compared to the density of vias and signal traces on PCB 100 of FIG. 1.

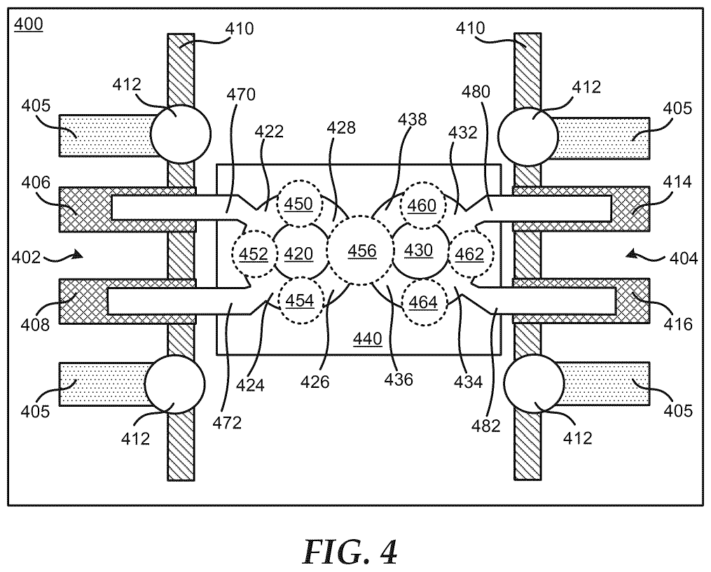

FIG. 3 illustrates a portion of a PCB 300 of an information handling system, such as information handling system 700 of FIG. 7, according to at least one embodiment of the present disclosure. PCB 300 includes differential pairs 302 and 304 and ground pads 305. Differential pair 302 includes pads 306 and 308. Each ground pad 305 may be physically and electrically coupled to a ground layer 310 of PCB 300 by a respective ground via 312. Additionally, a different ground trace may be routed between a respective ground pad 305 and corresponding ground via 312. Differential pair 304 includes pads 314 and 316. PCB 300 also includes vias 320 and 330 and an anti-pad 340. PCB 300 may include additional components without varying from the scope of this disclosure.

Via 320 is divided into separate via portions 322, 324, 326, and 328, and via 330 is divided into separate via portions 332, 334, 336, and 338. In an example, vias 320 and 330 may be plated with any suitable conductive material including, but not limited to, copper, silver, gold, zinc, and nickel. The details of PCB manufacture, and particularly the forming of vias in a PCB are known in the art and will not be further described herein, except as needed to illustrate the current embodiments.

After via 320 has been plated, sections 350, 352, 354, and 356 of the plating of the via may be removed in any suitable manner. For example, a drill may be utilized to drill holes corresponding to sections 350, 352, 354, and 356 in via 320 as shown in FIG. 3. After sections 350, 352, 354, and 356 are removed from via 320, the via is separated into via portions 322, 324, 326, and 328. In an example, via portion 322 may be physically and electrically connected to differential trace 306 and a signal layer within PCB 300. Similarly, via portion 324 may be physically and electrically connected to differential trace 308 and a signal layer within PCB 300. Via portions 326 and 328 may be physically and electrically connected to ground traces 305 and a ground layer within PCB 300.

In an example, removed sections 350 and 354 would preferably be located along a line of symmetry for via 320 and removed sections 352 and 356 would preferably be located along another line of symmetry for via 320. In an example, the line of symmetry for removed sections 350 and 354 may be substantially perpendicular to the line of symmetry for removed sections 352 and 356. In an example, based on removed sections 350 and 354 being located along a line of symmetry and removed sections 352 and 356 being located along another line of symmetry, via portions 322, 324, 326, and 328 may be the same size.

In an exemplary embodiment, the outer diameter of via 320 may be 25 mil and the diameter of each of removed sections 350, 352, 354 and 356 may be 15 mil. In this embodiment, a distance from the center of removed section 350 to the center of removed section 354 may be 25 mil, a distance from the center of removed section 350 to the center of via 320 may be 12.5 mil, and a distance from the center of removed section 352 to the center of signal via 320 may be 12.5 mil. Similarly, a distance from the center of removed section 352 to the center of removed section 356 may be 25 mil, a distance from the center of removed section 352 to the center of via 320 may be 12.5 mil, and a distance from the center of removed section 356 to the center of signal via 320 may be 12.5 mil. One of ordinary skill in the art would recognize that mil is a unit of measurement utilized in routing on PCBs, and one mil equals one-thousandth of an inch or two hundred fifty-four ten-thousandths of a millimeter.

In certain examples, the locations for a drill to remove sections 350, 352, 354 and 356 may vary slightly, within a tolerance of +/−2 mil, in one or more directions from a desired drilling location. For example, the drill hole for removed section 350 may be slightly to the one side of the line of symmetry for signal via 320, and the drill hole for removed section 354 may also be slightly to the same or different side of the line of symmetry. Similarly, the drill hole for removed section 352 may be slightly to the one side of the other line of symmetry for signal via 320, and the drill hole for removed section 356 may also be slightly to the same or different side of the other line of symmetry. In this example, different via portions 322, 324, 326, and 328 may include more or less of the plating of via 320 than other via portions. In an example, a tolerance of the drill location for removed sections 350, 352, 354 and 356 may be such that via portions 322, 324, 326, and 328 may always include enough of the plating of via 320 to have a desired impedance, such as 85 ohms+/−10%, and to operate has needed for a differential pair.

After 330 has been plated, sections 360, 362, 364, and 356 of the plating of the via may be removed in any suitable manner. For example, a drill may be utilized to drill holes corresponding to sections 360, 362, 364, and 356 in via 330 as shown in FIG. 3. After sections 360, 362, 364, and 356 are removed from via 330, the via is separated into via portions 332, 334, 336, and 338. In an example, via portion 332 may be physically and electrically connected to differential trace 314 of differential pair 304 and a signal layer within PCB 300. Similarly, via portion 334 may be physically and electrically connected to differential trace 316 of differential pair 304 and a signal layer within PCB 300. Via portions 336 and 338 may be physically and electrically connected to ground traces 305 and ground layer 310 within PCB 300.

In an example, removed sections 360 and 364 would preferably be located along a line of symmetry for via 330 and removed sections 362 and 356 would preferably be located along another line of symmetry for via 320. In an example, the line of symmetry for removed sections 360 and 364 may be substantially perpendicular to the line of symmetry for removed sections 362 and 356. In an example, based on removed sections 360 and 364 being located along a line of symmetry and removed sections 362 and 356 being located along another line of symmetry, via portions 332, 334, 336, and 338 may be the same size.

In an exemplary embodiment, the outer diameter of via 330 may be 25 mil and the diameter of each of removed sections 360, 362, 364 and 356 may be 15 mil. In this embodiment, a distance from the center of removed section 360 to the center of removed section 364 may be 25 mil, a distance from the center of removed section 360 to the center of via 330 may be 12.5 mil, and a distance from the center of removed section 364 to the center of signal via 330 may be 12.5 mil. Similarly, a distance from the center of removed section 362 to the center of removed section 356 may be 25 mil, a distance from the center of removed section 362 to the center of via 330 may be 12.5 mil, and a distance from the center of removed section 356 to the center of signal via 330 may be 12.5 mil.

In certain examples, the locations for a drill to remove sections 360, 362, 364, and 356 may vary slightly, within a tolerance of +/−2 mil, in one or more directions from a desired drilling location. For example, the drill hole for removed section 360 may be slightly to the one side of the line of symmetry for signal via 330, and the drill hole for removed section 364 may also be slightly to the same or different side of the line of symmetry. Similarly, the drill hole for removed section 362 may be slightly to the one side of the other line of symmetry for signal via 330, and the drill hole for removed section 356 may also be slightly to the same or different side of the other line of symmetry. In this example, different ones of via portions 332, 334, 336, and 338 may include more or less of the plating of via 330 than other via portions. In an example, a tolerance of the drill location for removed sections 360, 362, 364 and 366 may be such that via portions 332, 334, 336, and 338 may always include enough of the plating of via 330 to have a desired impedance, such as 85 ohms+/−10%, and operate has needed for a differential pair.

In an example, via portions 322 and 324 may be signal portions of via 320, and via portions 326 and 328 may be ground portions of the via. Similarly, via portions 332 and 334 may be signal portions of via 330, and via portions 336 and 338 may be ground portions of the via. Based on this configuration of vias 320 and 330, both of vias 320 and 330 may include via portions that are part of corresponding differential pairs 302 and 304. For example, via portions 322 and 324 of via 320 for differential pair 302 and via portions 332 and 334 of via 330 for differential pair 302. Based on this configuration of vias 320 and 330, both of vias 320 and 330 may include via portions that are grounds for differential pairs 302 and 304. For example, via portions 324 and 328 of via 320 and via portions 336 and 338 of via 330. Signal via portion 322 is electrically and physically connected to pad 306 of differential pair 302 by a signal trace 370, and signal via portion 324 is electrically and physically connected to pad 308 of differential pair 302 by a signal trace 372. Similarly, signal via portion 332 is electrically and physically connected to pad 314 of differential pair 304 by a signal trace 380, and signal via portion 334 is electrically and physically connected to pad 316 of differential pair 304 by a signal trace 380.

Via 320 (via portions 326 and 328), via 330 (via portions 336 and 338), and ground vias 312 are utilized to interconnect two or more different metal layers within PCB 300. Additionally, vias 320 and 330, and ground vias 312 may be utilized to connect the two or more different metal layers within PCB 300 with metal traces and/or metal pads on a surface of the PCB, such as pads 305, 306, 308, 314, and 316. While portions 322 and 324 of via 320 are illustrated and described as connecting metal layers within PCB 300 to respective pads 306 and 308 through respective traces 370 and 372 on the surface of the PCB, traces 370 and 372 may be located within any signal layer within the PCB and portions 322 and 324 of via 320 may perform substantially similar functions without varying from the scope of this disclosure. While portions 332 and 334 of via 330 are illustrated and described as connecting metal layers within PCB 300 to respective pads 314 and 316 through respective traces 380 and 382 on the surface of the PCB, traces 380 and 382 may be located within any signal layer within the PCB and portions 332 and 324 of via 330 may perform substantially similar functions without varying from the scope of this disclosure.

In an example, ground portions 326 and 328 of via 320 may connect with ground pad 305 in any suitable manner. For example, ground portions 326 and 328 may connect with ground pad 305 through ground layer 310 and ground via 312. In an example, ground portions 326 and 328 may connect with ground pad 305 through a trace on the surface of PCB 300. In certain examples, ground portions 336 and 338 of via 330 may connect with ground pad 305 in any suitable manner. For example, ground portions 336 and 338 may connect with ground pad 305 through ground layer 310 and ground via 312. In an example, ground portions 336 and 338 may connect with ground pad 305 through a trace on the surface of PCB 300.

In certain examples, the conductive material plating of vias 320 and 330 may overlap, such that ground via portion 326 of via 320 and ground via portion 336 of via 330 may be interconnected with a continuous portion of conductive material. The interconnection between ground via portion 326 of via 320 and ground via portion 336 of via 330 may be referred to as ground webbing. In an example, ground via portion 328 of via 320 and ground via portion 338 of via 330 may be interconnected with a continuous portion of conductive material. The interconnection between ground via portion 328 of via 320 and ground via portion 338 of via 330 may be referred to as ground webbing. In an example, ground via portions 326 and 328 of via 320 and ground via portions 336 and 338 of via 330 may provide shielding between differential pairs 302 and 304. In certain examples, the ground webbing of ground via portions 326 and 336 and ground webbing of ground via portions 328 and 338 may block or reduce common mode noise and reduce or block crosstalk between differential pairs 302 and 304. Based on the blocking or reducing of common mode noise and crosstalk between differential pairs 302 and 304, the signal integrity of differential signals transmitted on the differential pairs improves.

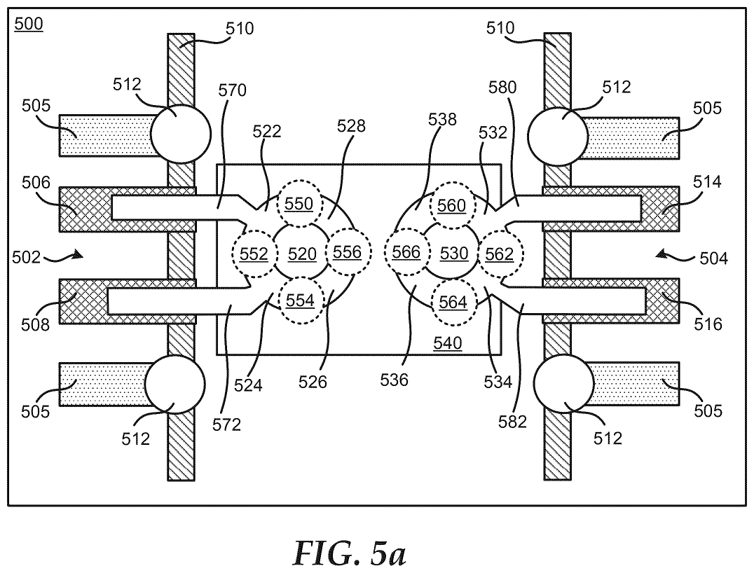

FIG. 4 illustrates a PCB 400 according to an embodiment of this disclosure. PCB 400 may be substantially similar to PCB 300 of FIG. 3. PCB 400 includes differential pairs 402 and 404 and ground pads 405. Differential pair 402 includes pads 406 and 408. Each ground pad 405 may be physically and electrically coupled to a ground layer 410 of PCB 400 by a respective ground via 412. Additionally, a different ground trace may be routed between a respective ground pad 405 and corresponding ground via 412. Differential pair 404 includes pads 414 and 416. PCB 400 also includes vias 420 and 430 and an anti-pad 440. PCB 400 may include additional components without varying from the scope of this disclosure.

As similarly described above with respect to FIG. 3, via portions 422, 424, 426, and 428 may be formed by removing sections 450, 452, 454 and 456 from a conductive plating of via 420. Similarly, via portions 432, 434, 436, and 438 may be formed by removing sections 460, 462, 464 and 456 from a conductive plating of via 430. Via portion 422 may be electrically and physically connected to signal trace 470 and signal pad 406 of differential pair 402, and via portion 424 may be electrically and physically connected to signal trace 472 and signal pad 408 of differential pair 402. In an example, via portions 422 and 424 may be connected to respective signal traces 470 and 472 and pads 406 and 408 of differential pair 402 in a substantially similar manner as described above with respect to FIG. 3. Via portion 432 may be electrically and physically connected to signal trace 480 and signal pad 414 of differential pair 404, and via portion 434 may be electrically and physically connected to signal trace 482 and signal pad 416 of differential pair 404. In an example, via portions 432 and 434 may be connected to respective signal traces 480 and 482 and pads 414 and 416 of differential pair 404 in a substantially similar manner as described above with respect to FIG. 3.

In an example, via portions 422 and 424 may be signal via portions such that these via portions may connect electrically and physically to respective signal traces 470 and 472 on the surface of PCB 400 with corresponding signal layers within the PCB. Similarly, via portions 432 and 434 may be signal via portions such that these via portions may connect electrically and physically to respective signal traces 480 and 482 on the surface of PCB 400 with corresponding signal layers within the PCB. In certain examples, via portions 426 and 428 may be physically and electrically connected to ground traces 405 and ground layer 410 within PCB 400. Similarly, via portions 436 and 438 may be physically and electrically connected to ground traces 405 and ground layer 410 within PCB 400.

In certain examples, removed section 456 may be substantially large enough that the conductive material plating of vias 420 and 430 do not overlap, such that a gap exists between ground via portion 426 of via 420 and ground via portion 436 of via 430. In an example, removed section 456 may be substantially large enough that conductive material of ground via portion 428 of via 420 and ground via portion 438 of via 430 do not overlap. In certain examples, ground via portions 426 and 428 of via 420 and ground via portions 436 and 438 of via 430 may provide shielding between differential pairs 402 and 404. The separation between ground via portions 426 and 436 and ground via portions 428 and 438 prevent return currents from being shared across differential pairs 402 and 404. Ground via portions 426 and 436 and ground via portions 428 and 438 may block or reduce common mode noise and reduce or block crosstalk between differential pairs 402 and 404. Based on the blocking or reducing of common mode noise and crosstalk between differential pairs 402 and 404, the signal integrity of differential signals transmitted on the differential pairs may improve.

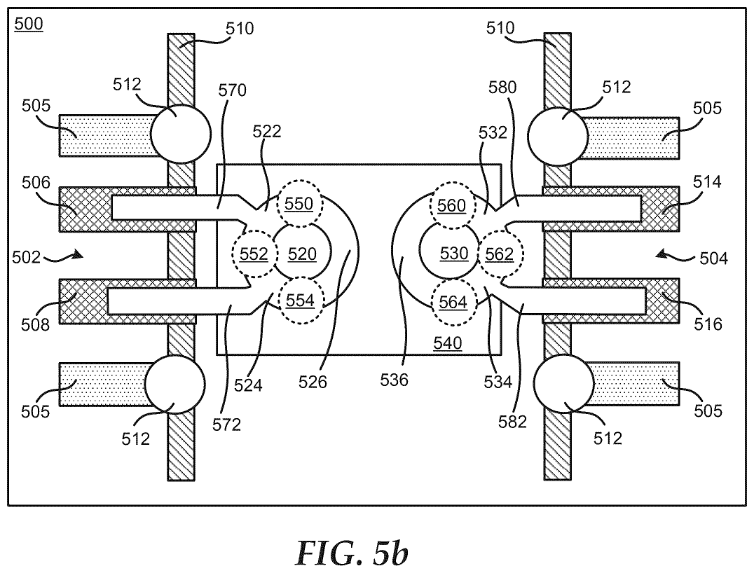

FIG. 5a illustrates a PCB 500 according to an embodiment of this disclosure. PCB 500 may be substantially similar to PCB 300 of FIG. 3. PCB 500 includes differential pairs 502 and 504 and ground pads 505. Differential pair 502 includes pads 506 and 508. Each ground pad 505 may be physically and electrically coupled to a ground layer 510 of PCB 500 by a respective ground via 512. Additionally, a different ground trace may be routed between a respective ground pad 505 and corresponding ground via 512. Differential pair 504 includes pads 514 and 516. PCB 500 also includes vias 520 and 530 and an anti-pad 540. PCB 500 may include additional components without varying from the scope of this disclosure.

As similarly described above with respect to FIG. 3, via portions 522, 524, 526, and 528 may be formed by removing sections 550, 552, 554 and 556 from a conductive plating of via 520. Similarly, via portions 532, 534, 536, and 538 may be formed by removing sections 560, 562, 564 and 566 from a conductive plating of via 530. Via portion 522 may be electrically and physically connected to signal trace 570 and signal pad 506 of differential pair 502, and via portion 524 may be electrically and physically connected to signal trace 572 and signal pad 508 of differential pair 502. In an example, via portions 522 and 524 may be connected to respective signal traces 570 and 572 and pads 506 and 508 of differential pair 502 in a substantially similar manner as described above with respect to FIG. 3. Via portion 532 may be electrically and physically connected to signal trace 580 and signal pad 514 of differential pair 504, and via portion 534 may be electrically and physically connected to signal trace 582 and signal pad 516 of differential pair 504. In an example, via portions 532 and 534 may be connected to respective signal traces 580 and 582 and pads 514 and 516 of differential pair 504 in a substantially similar manner as described above with respect to FIG. 3.

In an example, via portions 522 and 524 may be signal via portions such that these via portions may connect electrically and physically to respective signal traces 570 and 572 on the surface of PCB 500 with corresponding signal layers within the PCB. Similarly, via portions 532 and 534 may be signal via portions such that these via portions may connect electrically and physically to respective signal traces 580 and 582 on the surface of PCB 500 with corresponding signal layers within the PCB. In certain examples, via portions 526 and 528 may be physically and electrically connected to ground traces 505 and ground layer 510 within PCB 500. Similarly, via portions 536 and 538 may be physically and electrically connected to ground traces 505 and ground layer 510 within PCB 500.

In certain examples, vias 520 and 530 may be located far enough from each other that the conductive material plating of vias 520 and 530 do not overlap, such that a gap exists between ground via portion 526 of via 520 and ground via portion 536 of via 530. Similarly, the conductive material of ground via portion 528 of via 520 and ground via portion 538 of via 530 do not overlap. In certain examples, ground via portions 526 and 528 of via 520 and ground via portions 536 and 538 of via 530 may provide shielding between differential pairs 502 and 504. The separation between ground via portions 526 and 536 and ground via portions 528 and 538 prevent return currents from being shared across differential pairs 502 and 504. Ground via portions 526 and 536 and ground via portions 528 and 538 may block or reduce common mode noise and reduce or block crosstalk between differential pairs 502 and 504. Based on the blocking or reducing of common mode noise and crosstalk between differential pairs 502 and 504, the signal integrity of differential signals transmitted on the differential pairs may improve.

FIG. 5b illustrates another configuration of PCB 500 according to an embodiment of this disclosure. PCB 500 may be substantially similar to PCB 300 of FIG. 3. PCB 500 includes differential pairs 502 and 504 and ground pads 505. Differential pair 502 includes pads 506 and 508. Each ground pad 505 may be physically and electrically coupled to a ground layer 510 of PCB 500 by a respective ground via 512. Additionally, a different ground trace may be routed between a respective ground pad 505 and corresponding ground via 512. Differential pair 504 includes pads 514 and 516. PCB 500 also includes vias 520 and 530 and an anti-pad 540. PCB 500 may include additional components without varying from the scope of this disclosure.

As similarly described above with respect to FIG. 5, via portions 522, 524, and 526 may be formed by removing sections 550, 552, and 554 from a conductive plating of via 520. Similarly, via portions 532, 534, and 536 may be formed by removing sections 560, 562, and 564 from a conductive plating of via 530. Via portion 522 may be electrically and physically connected to signal trace 570 and signal pad 506 of differential pair 502, and via portion 524 may be electrically and physically connected to signal trace 572 and signal pad 508 of differential pair 502. In an example, via portions 522 and 524 may be connected to respective signal traces 570 and 572 and pads 506 and 508 of differential pair 502 in a substantially similar manner as described above with respect to FIG. 3. Via portion 532 may be electrically and physically connected to signal trace 580 and signal pad 514 of differential pair 504, and via portion 534 may be electrically and physically connected to signal trace 582 and signal pad 516 of differential pair 504. In an example, via portions 532 and 534 may be connected to respective signal traces 580 and 582 and pads 514 and 516 of differential pair 504 in a substantially similar manner as described above with respect to FIG. 3.

In an example, via portions 522 and 524 may be signal via portions such that these via portions may connect electrically and physically to respective signal traces 570 and 572 on the surface of PCB 500 with corresponding signal layers within the PCB. Similarly, via portions 532 and 534 may be signal via portions such that these via portions may connect electrically and physically to respective signal traces 580 and 582 on the surface of PCB 500 with corresponding signal layers within the PCB. In certain examples, via portion 526 may be physically and electrically connected to ground traces 505 and ground layer 510 within PCB 500. Similarly, via portion 536 may be physically and electrically connected to ground traces 505 and ground layer 510 within PCB 500.

In certain examples, vias 520 and 530 may be located far enough from each other that the conductive material plating of vias 520 and 530 do not overlap, such that a gap exists between ground via portion 526 of via 520 and ground via portion 536 of via 530. In certain examples, ground via portion 526 of via 520 and ground via portion 536 of via 530 may provide shielding between differential pairs 502 and 504. The separation between ground via portions 526 and 536 prevent return currents from being shared across differential pairs 502 and 504. Ground via portions 526 and 536 may block or reduce common mode noise and reduce or block crosstalk between differential pairs 502 and 504. Based on the blocking or reducing of common mode noise and crosstalk between differential pairs 502 and 504, the signal integrity of differential signals transmitted on the differential pairs may improve. In an example, ground via portion 526 may be a ground shield for via 520 and ground via portion 536 may be a ground via for via 530. In this example, the ground shields formed by ground via portions 526 and 536 as illustrated in FIG. 5b may be more solid than ground shields formed from ground via portions 526 and 528 and ground via portions 536 and 538 as illustrated in FIG. 5a. Additionally, ground via portions 526 and 536 may provide better blocking or reducing of common mode noise and crosstalk between differential pairs 502 and 504 as compared to ground via portions 526, 528, 536, and 538 of FIG. 5a.

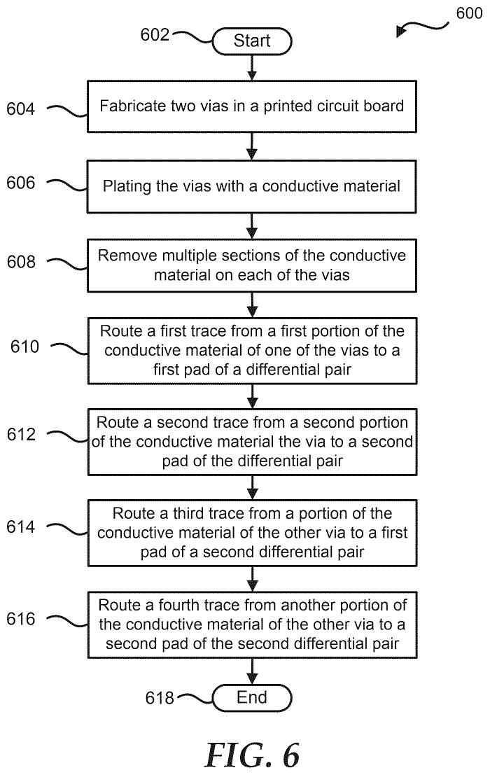

FIG. 6 is a flow diagram of method 600 for creating two different signal vias and connecting the differential signal vias to pads of two differential pairs according to at least one embodiment of the present disclosure, starting a block 602. It will be readily appreciated that not every method step set forth in this flow diagram is always necessary, and that certain steps of the methods may be combined, performed simultaneously, in a different order, or perhaps omitted, without varying from the scope of the disclosure.

At block 604, two vias are fabricated in a PCB. In an example, the vias may be any suitable type of via including, but not limited to, a through hole vias, a micro vias, and a skip vias. At block 606, the vias are plated with a conductive material. In an example, the conductive material may be copper. The details of PCB manufacture, and particularly the forming of vias and traces on a PCB are known in the art and will not be further described herein, except as needed to illustrate the current embodiments.

At block 608, multiple sections of the conductive material plated on each of the vias are removed. In an example, the multiple sections may be removed by any suitable manner, such as drilling the multiple sections out of the conductive material or the like from both of the vias. In certain examples, the removal of the multiple sections may create first, second, third, and fourth via portions of the conductive material plated on the via. In an example, the removal of the multiple sections may create first, second, third, and fourth via portions of the conductive material plated on the second via.

At block 610, a first trace is routed from the first via portion of the conductive material on one via to a first pad of a differential pair. At block 612, a second trace is routed from the second via portion of the conductive material on the one via to a second pad of the differential pair. In an example, the electrical communication from the first pad to the first portion of the conductive material of one via through the first trace may provide a first signal path for a first differential signal transmitted on the differential pair. The electrical communication from the second pad to the second portion of the conductive material on the one via through the second trace may provide a second signal path for the differential signal. At block 614, a third trace is routed from a portion of the conductive material on the other via to a first pad of a second differential pair. At block 616, a fourth trace is routed from another portion of the conductive material on the other via to a second pad of the second differential pair, and the flow ends at block 618. In an example, the electrical communication from the first pad to the portion of the conductive material of the other via through the third trace may provide a first signal path for a first differential signal transmitted on the second differential pair. The electrical communication from the second pad to another portion of the conductive material on the other via through the fourth trace may provide a second signal path for the second differential signal.

FIG. 7 illustrates a generalized embodiment of an information handling system 700. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 700 can include processing resources for executing machine-executable code, such as a central processing unit (CPU), a programmable logic array (PLA), an embedded device such as a System-on-a-Chip (SoC), or other control logic hardware. Information handling system 700 can also include one or more computer-readable medium for storing machine-executable code, such as software or data. Additional components of information handling system 700 can include one or more storage devices that can store machine-executable code, one or more communications ports for communicating with external devices, and various input and output (I/O) devices, such as a keyboard, a mouse, and a video display. Information handling system 700 can also include one or more buses operable to transmit information between the various hardware components.

Information handling system 700 can include devices or modules that embody one or more of the devices or modules described below, and operates to perform one or more of the methods described below. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756, a disk emulator 760 connected to an external solid state drive (SSD) 762, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756, disk emulator 760, SSD 762, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708. Memory 720 is connected to processor 702 via a memory interface 722. Memory 725 is connected to processor 704 via a memory interface 727. Graphics interface 730 is connected to I/O interface 710 via a graphics interface 732, and provides a video display output 736 to a video display 734. In a particular embodiment, information handling system 700 includes separate memories that are dedicated to each of processors 702 and 704 via separate memory interfaces. An example of memories 720 and 730 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 1394 (Firewire) interface, a proprietary interface, or a combination thereof. Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712, or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof. Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700. Management device 790 can operate off of a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A printed circuit board of an information handling system, the printed circuit board comprising:
a first via fabricated through the printed circuit board, wherein the first via includes a first conductive metal plating, the first via includes;
a first via portion connected to a first trace of a first differential pair of the printed circuit board;
a second via portion connected to a second trace of the first differential pair of the printed circuit board; and
third and fourth via portions connected to a ground plane layer of the printed circuit board, wherein the first, second, third, and fourth via portions are formed in the first conductive metal plating; and
a second via fabricated through the printed circuit board, wherein the second via includes a second conductive metal plating, the second via includes;
a fifth via portion connected to a first trace of a second differential pair of the printed circuit board;
a sixth via portion connected to a second trace of the second differential pair of the printed circuit board; and
seventh and eighth via portions connected to the ground plane layer of the printed circuit board, wherein the fifth, sixth, seventh, and eighth via portions are formed in the second conductive metal plating.

1. The printed circuit board of claim 1, wherein the first and second conductive metal plating are a same conductive metal plating.

2. The printed circuit board of claim 2, wherein the third via portion and the seventh via portion are interconnected and form a ground webbing between the first and second differential pair.

3. The printed circuit board of claim 3, wherein the fourth via portion and the eighth via portion are interconnected and form a ground webbing between the first and second differential pair.

4. The printed circuit board of claim 1, wherein the third, fourth, seventh, and eighth via portions shield a first differential signal on the first differential pair from a second differential signal on the second differential pair.

5. The printed circuit board of claim 1, wherein a first gap is located between the third via portion and the seventh via portion.

6. The printed circuit board of claim 6, wherein a second gap is located between the fourth via portion and the eighth via portion.

7. The printed circuit board of claim 7, wherein the first and second gaps prevent a return current from being shared across the first and second differential pairs.

8. The printed circuit board of claim 1, wherein a section of both the first and second conductive metal plating is removed to create the first and second gaps.

9. An information handling system comprising:
a printed circuit board including:
a first via fabricated through the printed circuit board, wherein the first via includes a first conductive metal plating, the first via includes;
a first via portion connected to a first trace of a first differential pair of the printed circuit board;
a second via portion connected to a second trace of the first differential pair of the printed circuit board; and
third and fourth via portions connected to a ground plane layer of the printed circuit board, wherein the first, second, third, and fourth via portions are formed in the first conductive metal plating, wherein first, second, third, and fourth sections of the first conductive metal plating are removed to form the first, second, third, and fourth via portions; and
a second via fabricated through the printed circuit board, wherein the second via includes a second conductive metal plating, the second via includes;
a fifth via portion connected to a first trace of a second differential pair of the printed circuit board;
a sixth via portion connected to a second trace of the second differential pair of the printed circuit board; and
seventh and eighth via portions connected to the ground plane layer of the printed circuit board, wherein the fifth, sixth, seventh, and eighth via portions are formed in the second conductive metal plating.

10. The information handling system of claim 10, wherein the first and second conductive metal plating are a same conductive metal plating.

11. The information handling system of claim 11, wherein the third via portion and the seventh via portion are interconnected and form a ground webbing between the first and second differential pair.

12. The information handling system of claim 12, wherein the fourth via portion and the eighth via portion are interconnected and form a ground webbing between the first and second differential pair.

13. The information handling system of claim 10, wherein the third, fourth, seventh, and eighth via portions shield a first differential signal on the first differential pair from a second differential signal on the second differential pair.

14. The information handling system of claim 10, wherein a first gap is located between the third via portion and the seventh via portion.

15. The information handling system of claim 15, wherein a second gap is located between the fourth via portion and the eighth via portion.

16. The information handling system of claim 10, wherein the first and second gaps prevent a return current from being shared across the first and second differential pairs.

17. A method comprising:
fabricating first and second vias in a printed circuit board of an information handling system;
plating the first via with a first conductive material;
removing multiple sections of the first via to create first, second, third, and fourth via portions of the first via;
routing a first trace from the first via portion to a first pad of a first differential pair;
routing a second trace from the second via portion to a second pad of the first differential pair;
plating the second via with a second conductive material;
removing multiple sections of the second via to create fifth, sixth, seventh, and eighth via portions of the second via;
routing a third trace from the fifth via portion to a first pad of a second differential pair; and
routing a fourth trace from the sixth via portion to a second pad of the second differential pair.

18. The method of claim 18, wherein an electrical communication from the first pad to the first via portion of the first conductive material through the first trace may provide a first signal path for a differential signal transmitted on the first differential pair.

19. The method of claim 18, wherein the third, fourth, seventh, and eighth via portions are connected to a ground plane layer of the printed circuit board.
